(19) United States
(12) Patent Application Publication
(10) Pub. No.: US 2008/0296686 A1
(43) Pub. Date: Dec. 4, 2008

(54) CIRCUIT BOARD AND DISPLAY APPARATUS

(76) Inventor: Wen-Jyh Sah, Tainan City (TW)

Correspondence Address: BIRCH STEWART KOLASCH & BIRCH, PO BOX 747, FALLS CHURCH, VA, 22040-0747, US

(21) Appl. No.: 12/119,200

(22) Filed: May 12, 2008

(30) Foreign Application Priority Data
May 28, 2007 (TW) 096119035

(51) Int. Cl. H01L 23/62

(52) U.S. Cl. 257/360; 257/E23.001

(57) ABSTRACT

A circuit board includes a transparent circuit substrate, at least one die and at least one electrostatic discharge (ESD) protection circuit. The transparent circuit substrate has a patterned conducting layer. The die is disposed on the transparent circuit substrate and has at least one input/output (I/O) electrical connecting pad. The ESD protection circuit is disposed on the transparent circuit substrate, and the ESD protection circuit is electrically connected with the I/O electrical connecting pad of the die through the patterned conducting layer. A display apparatus including the circuit board is also disclosed.

### CROSS REFERENCE TO RELATED APPLICATIONS

This Non-provisional application claims priority under 35 U.S.C. §119(a) on Patent Application No(s). 096119035 filed in Taiwan, Republic of China on May 28, 2007, the entire contents of which are hereby incorporated by reference.

### BACKGROUND OF THE INVENTION

1. Field of Invention

The present invention relates to a circuit board and a display apparatus.

2. Related Art

An integrated circuit (IC) is a high-technique micro electronic device, which has many micro electronic components integrated in a chip. Accompanying with the development of the IC technology, the electrostatic discharge (ESD) protection of the IC has become more and more important.

ESD is one of the factors inducing the electrical overstress (EOS) in most electronic devices or systems. EOS may cause the permanent damage of semiconductor devices and computer systems. Thus, the functions of the IC are affected and the products may malfunction. In general, the conventional circuit board has at least one chip for executing a certain function. FIG. 1 is a schematic diagram showing an active surface of a conventional chip 11. As shown in FIG. 1, the chip 11 includes a core circuit 111, a plurality of ESD protection circuits 112 and a plurality of input/output (I/O) pads 113. The ESD protection circuits 112 are disposed around the core circuit 111 for protecting the chip 11 from electrostatic. In addition, the ESD protection circuits 112 and the I/O pads 113 are alternately arranged.

Since the chip 11 must provide the layout area for the ESD protection circuits 112, the size thereof can not be reduced. Thus, the manufacturing cost can not be decreased, and the chip 11 will occupy a certain space on the circuit board.

Therefore, it is an important subject to provide a circuit board and a display apparatus that can reduce the size of the chip and still have the ESD protection function.

### SUMMARY OF THE INVENTION

In view of the foregoing, the invention is to provide a circuit board and a display apparatus that can reduce the size of the chip and still have the ESD protection function.

To achieve the above, the invention discloses a circuit board including a transparent circuit substrate, at least one die and at least one electrostatic discharge (ESD) protection circuit. The transparent circuit substrate has a patterned conducting layer. The die is disposed on the transparent circuit substrate and has at least one input/output (I/O) electrical connecting pad. The ESD protection circuit is disposed on the transparent circuit substrate and electrically connected with the I/O electrical connecting pad of the die through the patterned conducting layer.

In addition, the invention also discloses a display apparatus at least including a circuit board. The circuit board includes a transparent circuit substrate, at least one die and at least one ESD protection circuit. The transparent circuit substrate has a patterned conducting layer. The die is disposed on the transparent circuit substrate and has at least one I/O electrical connecting pad. The ESD protection circuit is disposed on the transparent circuit substrate and electrically connected with the I/O electrical connecting pad of the die through the patterned conducting layer.

As mentioned above, in the circuit board and display apparatus of the invention, the ESD protection circuit is disposed on the transparent circuit substrate and is electrically connected with the die. Compared with the prior art, the size of the die in the invention can be sufficiently decreased, so that the size of the circuit board can be reduced or the layout area can be increased.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a conventional circuit board;

FIG. 2A is a schematic diagram showing a circuit board according to a preferred embodiment of the invention;

FIG. 2B is a schematic diagram showing another circuit board according to the preferred embodiment of the invention;

FIG. 2C is a schematic diagram showing still another circuit board according to the preferred embodiment of the invention;

FIG. 3 is a top view of a circuit board according to the preferred embodiment of the invention;

FIG. 4 is a cross-sectional view of the circuit board taken along a line AA′ of FIG. 3;

FIG. 5 is a side view showing a display apparatus according to a first embodiment of the invention;

FIG. 6 is a side view showing a display apparatus according to a second embodiment of the invention.

### DETAILED DESCRIPTION OF THE INVENTION

The present invention will be apparent from the following detailed description, which proceeds with reference to the accompanying drawings, wherein the same references relate to the same elements.

### Embodiment of Circuit Board

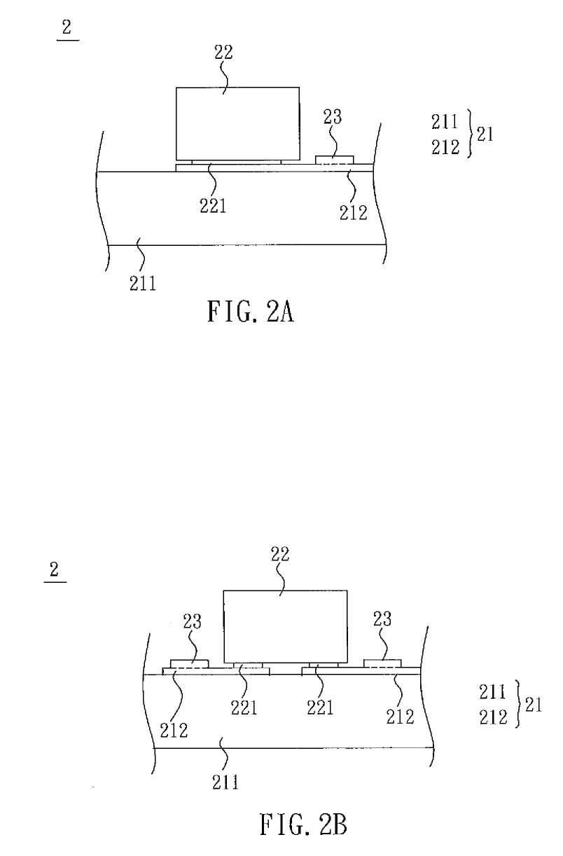

With reference to FIG. 2A, a circuit board 2 according to a preferred embodiment of the invention includes a transparent circuit substrate 21, a die 22 and an ESD protection circuit 23.

The transparent circuit substrate 21 has a transparent substrate 211 and a patterned conducting layer 212 disposed on one surface of the transparent substrate 211. In the embodiment, the transparent substrate 211 can be made of plastic or glass, which is light permeable. The patterned conducting layer 212 can be composed of a single metal layer or multiple metal layers. Alternatively, the patterned conducting layer 212 can be composed of a stacked layer including metal layers and insulating layers.

The die 22 is disposed on the transparent circuit substrate 21 and has at least one input/output (I/O) electrical connecting pad 221 for electrically connecting with the patterned conducting layer 212. The die 22 can be formed on the transparent circuit substrate 21 by way of flip-chip or wire bonding. In the present embodiment, the die 22 and the patterned conducting layer 212 are connected by way of flip-chip, for example. In this case, the connection of the die 22 can be easily performed due to the transparent circuit substrate 21, which is light permeable.

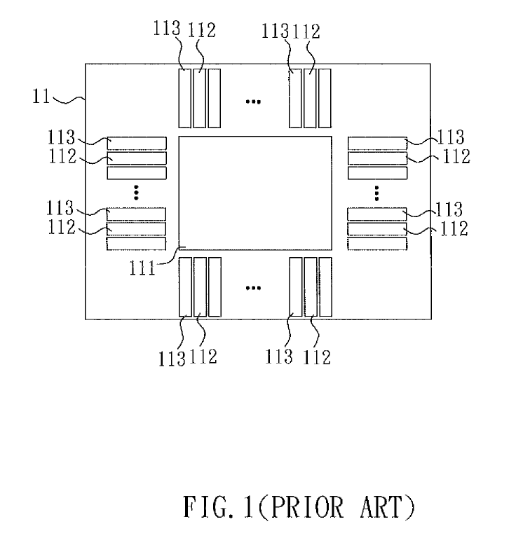

The ESD protection circuit 23 is disposed on the transparent circuit substrate 21 and electrically connected with the I/O electrical connecting pad 221 of the die 22 through the patterned conducting layer 212. Thus, the ESD protection circuit 23 can protect the die 22 from electrostatic. In the embodiment, the ESD protection circuit 23 is configured on the transparent circuit substrate 21, which is different from the conventional ESD protection circuit 112 disposed in the chip 11 as shown in FIG. 1. Therefore, the size of the die 22 of the invention can be decreased, so that the size of the circuit board 2 can be reduced or the layout area of the circuit board 2 can be increased.

Besides, the number and position of the ESD protection circuit 23 can be various depending on the actual requirements. For example, each die 22 may correspond to one ESD protection circuit 23 as shown in FIG. 2A, or each die 22 may correspond to two ESD protection circuits 23 as shown in FIG. 2B.

In the embodiment, the ESD protection circuit 23 is the circuit layout directly formed on the circuit board 2 by a semiconductor manufacturing process or a manufacturing process for a TFT transistor. Alternatively, the ESD protection circuit 23 can be formed simultaneously with other circuits or traces, such as the pixel electrode array. Thus, the manufacturing process of the ESD protection circuit 23 can be integrated with other trace manufacturing process, thereby reducing the total manufacturing steps of the circuit board 2.

Referring to FIG. 2C, the ESD protection circuit 23 can be a surface mount device (SMD). In this case, the ESD protection circuit 23 is surface mounted on the contact points of the transparent circuit substrate 21 by solder.

In addition, one end of the ESD protection circuit 23 is electrically connected with the I/O electrical connecting pad 221 of the die 22 through the patterned conducting layer 212, and the other end of the ESD protection circuit 23 is grounded or electrically connected with a DC power source (not shown). The ESD protection circuit 23 may include at least one diode, at least one transistor, at least one resistor, at least one capacitor, at least one inductance or at least one impedance element. For example, the ESD protection circuit 23 includes a first diode and a second diode. The positive end of the first diode is electrically connected with the I/O electrical connecting pad 221 of the die 22 through the patterned conducting layer 212. The negative end of the first diode and the positive end of the second diode are electrically connected with each other and are grounded or connected to a DC power source. The negative end of the second diode is electrically connected to the positive end of the first diode.

In the following illustration, the circuit board 2 is used as a thin-file transistor (TFT) substrate of a display panel.

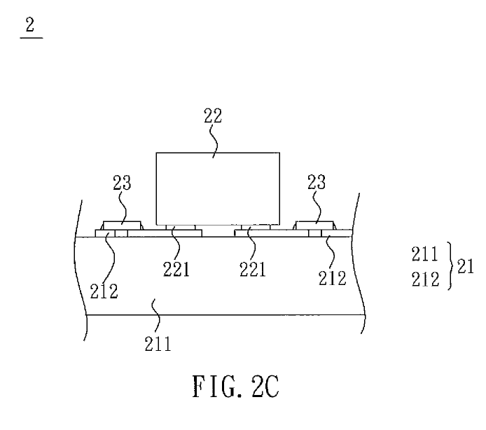

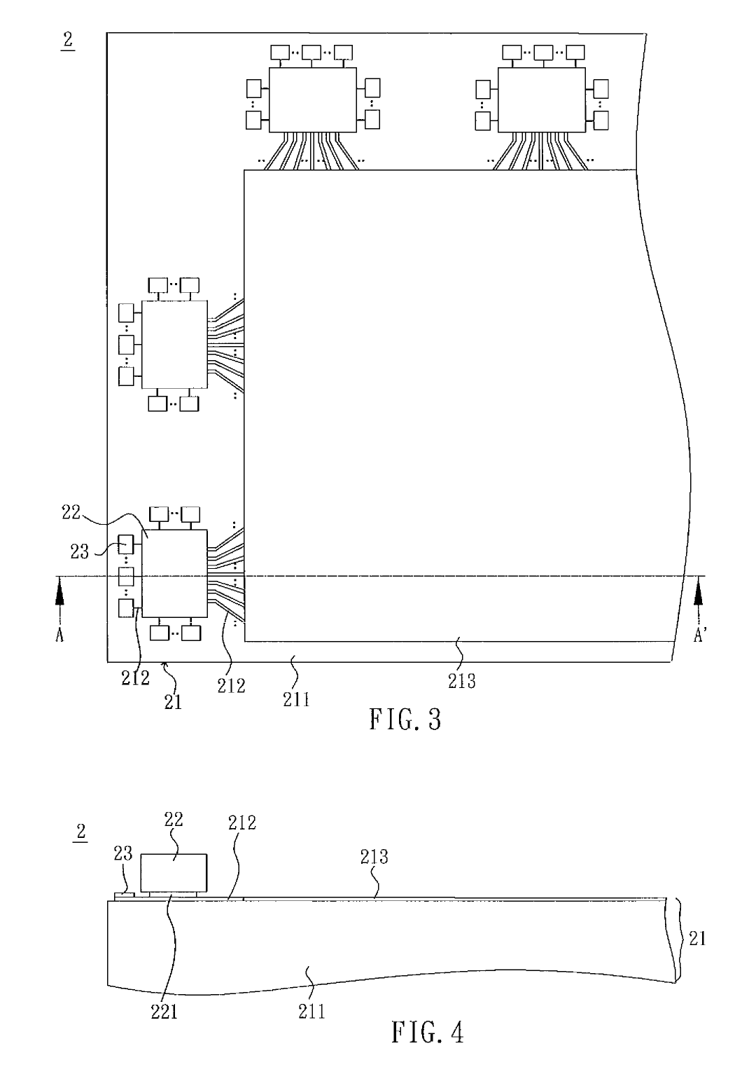

With reference to FIG. 3 and FIG. 4, the transparent circuit substrate 21 has a transparent substrate 211 and a patterned conducting layer 212. In the embodiment, the transparent substrate 211 is a glass substrate. The die 22 can be a driving chip such as a scan line driving chip or a data line driving chip. The die 22 can be electrically connected with the patterned conducting layer 212, which is formed on the transparent substrate 211, by the COG (Chip on Glass) process. Then, the ESD protection circuit 23 can be electrically connected with the die 22 through the patterned conducting layer 212.

In the embodiment, the transparent circuit substrate 21 may further include a pixel electrode array 213, which is disposed on a surface of the transparent substrate 211 and electrically connected with the patterned conducting layer 212. The pixel electrode array 213 can be composed of stacked layers including insulating layers, semiconductor layers, metal layers and conducting layers.

In the above mentioned circuit board 2, the ESD protection circuit 23 is disposed on the transparent circuit substrate 21 and electrically connected with the die 22. Compared with the prior art, the size of the die 22 can be sufficiently decreased, so that the size of the circuit board 2 can be reduced or the layout area can be increased.

### First Embodiment of Display Apparatus

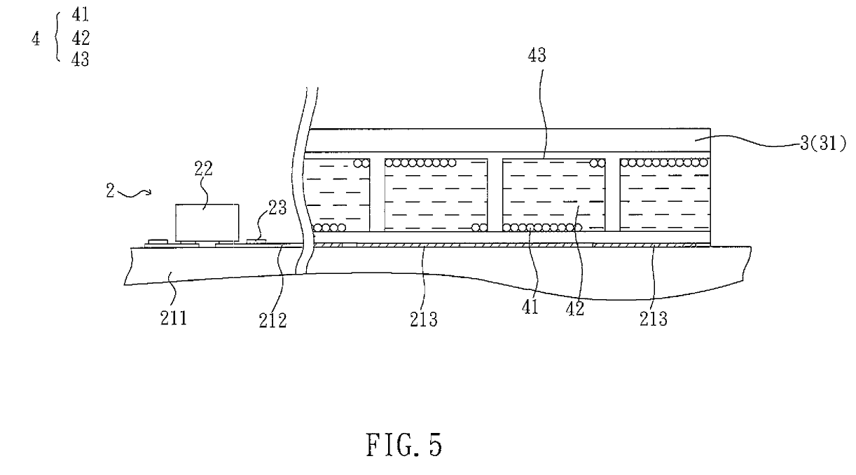

With reference to FIG. 5, a display apparatus according to a first embodiment of the invention includes a circuit board 2, an opposing electrode unit 3 and an opto-electronic display unit 4. Herein, the circuit board 2 is shown in FIG. 2B and is described in the above embodiment, so the detailed description thereof is omitted. In addition, when the display apparatus is an electrophoretic display apparatus, the opto-electronic display unit 4 includes an electrophoretic material. Alternatively, when the display apparatus is an electrowetting display apparatus, the opto-electronic display unit 4 includes an electrowetting material. In the embodiment, the display apparatus is an electrophoretic display apparatus for example.

The opposing electrode unit 3 is disposed opposite to the pixel electrode array 213 of the circuit board 2. The opposing electrode unit 3 may include an electrode layer 31, which is made of indium tin oxide (ITO), aluminum-doped zinc oxide (AZO), indium zinc oxide (IZO) or cadmium tin oxide.

The opto-electronic display unit 4 is disposed between the opposing electrode unit 3 and the pixel electrode array 213 of the circuit board 2. In the embodiment, the opto-electronic display unit 4 has an electrophoretic material, which includes a dielectric solvent 42 and a plurality of pigment particles 41 distributed in the dielectric solvent 42. The opto-electronic display unit 4 has, for example but not limited to, a plurality of micro-cup structures 43, and the electrophoretic material, including the pigment particles 41 and the dielectric solvent 42, is accommodated in the micro-cup structure 43. Alternatively, the electrophoretic material can be concentrated in a micro-capsule structure (not shown).

In the embodiment, the voltage difference between the opposing electrode unit 3 and the pixel electrode array 213 can be controlled, so that the pigment particles 41 can be driven and moved for presenting the color of the pigment particles 41 or the dielectric solvent 42 so as to show the desired color.

In the above mentioned display apparatus, the ESD protection circuit is disposed on the transparent circuit substrate and electrically connected with the die. Compared with the prior art, the size of the die can be sufficiently decreased, so that the size of the circuit board can be reduced or the layout area can be increased.

### Second Embodiment of Display Apparatus

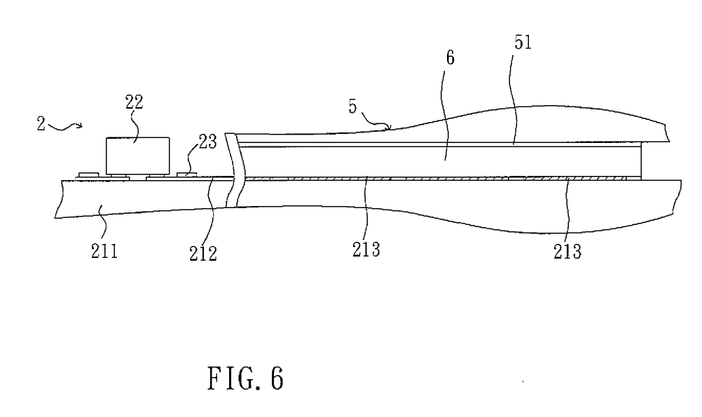

With reference to FIG. 6, a display apparatus according to a second embodiment of the invention is, for example, a liquid crystal display apparatus and includes a circuit board 2, a color filter substrate 5 and a liquid crystal layer 6. Herein, the circuit board 2 is shown in FIG. 2B and is described in the above embodiment, so the detailed description thereof is omitted.

The color filter substrate 5 has an opposing electrode layer 51 disposed opposite to the pixel electrode array 213. The liquid crystal layer 6 is disposed between the color filer substrate 5 and the pixel electrode array 213. In practice, the color filter substrate 5 may further include a filter layer. The color filter substrate 5 and the liquid crystal layer 6 can be designed according to the conventional technology, so the detailed descriptions thereof are omitted.

In summary, in the circuit board and display apparatus of the invention, the ESD protection circuit is disposed on the transparent circuit substrate and is electrically connected with the die. Compared with the prior art, the size of the die in the invention can be sufficiently decreased, so that the size of the circuit board can be reduced or the layout area can be increased.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A circuit board, comprising:
a transparent circuit substrate having a patterned conducting layer;
at least one die disposed on the transparent circuit substrate and having at least one input/output (I/O) electrical connecting pad; and
at least one electrostatic discharge (ESD) protection circuit disposed on the transparent circuit substrate, wherein the ESD protection circuit is electrically connected with the I/O electrical connecting pad of the die through the patterned conducting layer.

2. The circuit board according to claim 1, wherein the transparent circuit substrate further has a pixel electrode array electrically connected with the patterned conducting layer.

3. The circuit board according to claim 2, wherein the transparent circuit substrate further has a transparent substrate, and the patterned conducting layer and the pixel electrode array are disposed on the transparent substrate.

4. The circuit board according to claim 3, wherein a material of the transparent substrate comprises plastic or glass.

5. The circuit board according to claim 1, wherein the transparent circuit substrate is a thin-film transistor (TFT) substrate.

6. The circuit board according to claim 1, wherein the ESD protection circuit comprises a diode, a transistor, a resistor, a capacitor, an inductance or an impedance element, one end of the diode, the transistor, the resistor, the capacitor, the inductance or the impedance element is electrically connected to the I/O electrical connecting pad of the die through the patterned conducting layer, and the other end of the diode, the transistor, the resistor, the capacitor, the inductance or the impedance element is grounded or electrically connected to a DC power source.

7. The circuit board according to claim 1, wherein the ESD protection circuit is formed by a semiconductor manufacturing process.

8. The circuit board according to claim 1, wherein the ESD protection circuit is formed by a manufacturing process for a TFT transistor.

9. The circuit board according to claim 1, wherein the ESD protection circuit is a surface mount device (SMD) disposed on the transparent circuit substrate by surface mount technology.

10. A display apparatus, which at least comprises a circuit board, the circuit board comprising:
a transparent circuit substrate having a patterned conducting layer;
at least one die disposed on the transparent circuit substrate and having at least one input/output (I/O) electrical connecting pad; and
at least one electrostatic discharge (ESD) protection circuit disposed on the transparent circuit substrate, wherein the ESD protection circuit is electrically connected with the I/O electrical connecting pad of the die through the patterned conducting layer.

11. The display apparatus according to claim 10, wherein the transparent circuit substrate further has a pixel electrode array electrically connected with the patterned conducting layer.

12. The display apparatus according to claim 11, wherein the transparent circuit substrate further has a transparent substrate, and the patterned conducting layer and the pixel electrode array are disposed on the transparent substrate.

13. The display apparatus according to claim 12, wherein a material of the transparent substrate comprises plastic or glass.

14. The display apparatus according to claim 10, wherein the transparent circuit substrate is a thin-film transistor (TFT) substrate.

15. The display apparatus according to claim 10, wherein the ESD protection circuit comprises a diode, a transistor, a resistor, a capacitor, an inductance or an impedance element one end of the diode, the transistor, the resistor, the capacitor, the inductance or the impedance element is electrically connected to the I/O electrical connecting pad of the die through the patterned conducting layer, and the other end of the diode, the transistor, the resistor, the capacitor, the inductance or the impedance element is grounded or electrically connected to a DC power source.

16. The display apparatus according to claim 10, wherein the ESD protection circuit is formed by a semiconductor manufacturing process.

17. The display apparatus according to claim 10, wherein the ESD protection circuit is formed by a manufacturing process for a TFT transistor.

18. The display apparatus according to claim 10, further comprising:
an opposing electrode unit disposed opposite to the circuit board; and
an opto-electronic display unit disposed between the opposing electrode unit and the circuit board.

19. The display apparatus according to claim 18, wherein the opto-electronic display unit comprises an electrophoretic material or an electrowetting material.

20. The display apparatus according to claim 10, further comprising:
a color filter substrate disposed opposite to the circuit board; and
a liquid crystal layer disposed between the color filter substrate and the circuit board.
